(19) United States
(12) Patent Application Publication
(10) Pub. No.: US 2013/0319524 A1
(43) Pub. Date: Dec. 5, 2013

(54) SOLAR ENERGY CONCENTRATOR WITH MULTIPLEXED DIFFRACTION GRATINGS

(71) Applicant: Prism Solar Technologies Incorporated, Highland, NY (US)

(72) Inventors: Eric D. Aspnes, Tucson, AZ (US); Jose E. Castillo-Aguilella, Tucson, AZ (US); Ryan D. Courreges, Tucson, AZ (US); Paul S. Hauser, Tucson, AZ (US); Kevin R. Stewart, Niskayuna, NY (US)

(21) Appl. No.: 13/874,633

(22) Filed: May 1, 2013

Related U.S. Application Data
(63) Continuation-in-part of application No. 13/743,122, filed on Jan. 16, 2013.
Application No. 13/743,122 is a continuation-in-part of application No. 13/682,199, filed on Nov. 20, 2012.
Application No. 13/682,199 is a continuation-in-part of application No. 13/675,855, filed on Nov. 13, 2012.
(60) Provisional application No. 61/641,143, filed on May 1, 2012.
(60) Provisional application No. 61/643,448, filed on May 7, 2012.

(51) Int. Cl. H01L 31/052

(52) U.S. Cl. CPC H01L 31/0522
USPC 136/259

(57) ABSTRACT

A solar-energy concentrator and method for collecting sunlight with the concentrator. The concentrator includes a photovoltaic (PV) module having a PV cell and layers containing holographically-defined diffraction gratings that are spatially stacked or multiplexed. Spatial stacking or multiplexing of the gratings is configured to ensure that one grating layer carries another grating layer and that a portion of incident light not diffracted on one grating interacts with and is diffracted by another grating. Light that has interacted with either of the spatially multiplexed gratings is further redirected towards a sunlight collecting surface of the PV cell with the use of TIR reflection at a dielectric boundary of the concentrator.

### CROSS-REFERENCE TO RELATED APPLICATIONS

The present application claims benefit of and priority from the U.S. Provisional Applications Nos. 61/641,143 filed on May 1, 2012 and titled “Solar Energy Concentrator With Multiplexed Diffraction Gratings”; and 61/643,448 filed on May 7, 2012 and titled “Holographic Planer Concentrator”.

The present application is also a continuation-in-part of the co-pending U.S. patent applications Ser. No. 13/743,122 filed on Jan. 16, 2013 and titled “Bussing for PV-Module with Unequal-Efficiency Bi-Facial PV-Cells”; Ser. No. 13/682,119 filed on Nov. 20, 2012 and titled “Encapsulated Solar Energy Concentrator”; and Ser. No. 13/675,855 filed Nov. 13, 2012 and titled “Flexible Photovoltaic Module”.

The disclosure of each of the above-mentioned patent applications is incorporated herein by reference in its entirety.

### TECHNICAL FIELD

The present invention relates to system and method for fabrication of a holographic PV-module-based solar-power concentrator and, more particularly, to systems and methods employing diffraction gratings, spatially multiplexed as layers of the solar power concentrator, to increase the amount of solar energy incident onto the PV cell.

### BACKGROUND

Solar energy will satisfy an important part of future energy needs. While the need in solar energy output has grown dramatically in recent years, the total output from all solar installations worldwide still remains around 7 GW, which is only a tiny fraction of the world's energy requirement. High material and manufacturing costs, low solar module efficiency, and shortage of refined silicon limit the scale of solar power development required to effectively compete with the use of coal and liquid fossil fuels.

The key issue currently faced by the solar industry is how to reduce system cost per unit of efficiency of energy conversion. The main-stream technologies that are being explored to improve the cost-per-kilowatt of solar power are directed to (i) improving the efficiency of a solar cell that comprises solar modules, and (ii) delivering greater amounts of solar radiation onto the solar cell. In particular, these technologies include developing thin-film, polymer, and dye-sensitized photovoltaic (PV) cells to replace expensive semiconductor material based solar cells, the use high-efficiency smaller-area photovoltaic devices, and implementation of low-cost collectors and concentrators of solar energy.

While the reduction of use of semiconductor-based solar cells is showing great promise, for example, in central power station applications, it remains disadvantageous for residential applications due to the form factor and significantly higher initial costs. Indeed, today's residential solar arrays are typically fabricated with silicon photovoltaic cells, and the silicon material constitutes the major cost of the module. Therefore techniques that can reduce the amount of silicon used in the module without reducing output power will lower the cost of the modules.

The use of devices adapted to concentrate solar radiation on a solar cell is one of such techniques. Various light concentrators have been disclosed in related art, for example a compound parabolic concentrator (CPC); a planar concentrator such as, for example, a holographic planar concentrator (HPC) including a planar highly transparent plate and a holographically-recorded optical element mounted on its surface; and a spectrum-splitting concentrator (SSC) that includes multiple, single junction PV cells that are separately optimized for high efficiency operation in respectively-corresponding distinct spectral bands. A conventionally-used HPC is known to be limited in that the collection angle, within which the incident solar light is diffracted to illuminate the solar cell, is limited to about 45 degrees. Production of a typical SSC, on the other hand, requires the use of complex fabrication techniques.

In most of the existing systems used for concentration of solar radiation that employ holographic diffractive gratings, the manner in which the gratings are disposed in relation to a given PV cell is of substantial importance, as it influences the efficiency of sun-light collection and redirection of the collected light towards the PV cell.

### SUMMARY OF THE INVENTION

Embodiments of the invention provide a system and method for concentration of solar energy. In one embodiment, a solar energy concentrator having a front configured to be exposed to sunlight is provided. Such concentrator includes a photovoltaic (PV) module layer having a PV cell that defines a plane corresponding to the front; a first diffraction grating; and a second diffraction grating corresponding to the front. The second diffraction grating is adapted such that sunlight that has interacted with this grating also interacts with the first diffraction grating. In one implementation, for example, the second diffraction grating is configured to transmit a portion of sunlight from the front towards the first diffraction grating. Either or both of the first and second diffraction gratings optionally include(s) a holographic diffraction grating. In one specific case, the first and second holographic diffraction gratings can overlap in space and be volumetrically multiplexed. In a related embodiment, the first and second diffraction gratings have substantially co-extensive normal projections on the plane defined by the PV cell and, in a specific case, adjoin one another. For example, the first diffraction grating may be positioned behind the second diffraction grating as viewed from the front. An embodiment of a solar energy concentrator may further contain an optical layer separating and/or encapsulating the first and second diffraction gratings. In addition or alternatively, the light concentrator may be configured to ensure that light that has interacted with the first diffraction grating is totally internally reflected by a surface of the optical layer towards the PV cell. A PV cell of an embodiment may include a monofacial PV cell and/or a bifacial PV cell.

A specific embodiment of a solar energy concentrator employing a bifacial PV cell optionally additionally contains first and second optically-transparent substrates sandwiching the PV module layer and the first and second diffraction gratings such as to define an optical stack of layers. In such a stack, the second substrate corresponds to the front and the optical stack is configured to ensure that light that has interacted with the second diffraction grating is totally internally reflected by a surface of the optical stack towards the PV cell, and that light that has interacted with the first diffraction grating is totally internally reflected by a surface of the optical stack towards the bifacial PV cell. In particular, a surface of the optical stack reflecting light that has interacted with the second diffraction grating may include a surface of the second substrate. It is appreciated that additional thin-film layers (such as reflectance enhancing layers, for example) may be added at least to a surface of the embodiment at which the total internal reflection occurs to reflect light incident upon such surface outside of the angle of total internal reflection.

Embodiments of the invention additionally provide a method for collecting sunlight with a planar layered solar energy concentrator having a front and a photovoltaic (PV) cell. The method includes (i) receiving sunlight at a first diffraction grating defining a first optical layer of the concentrator where the first diffraction grating corresponding to the front, and (ii) transmitting at least a portion of light received with the first diffraction grating to a second diffraction grating defining a second optical layer of the concentrator, where the second optical layer is configured to carry the first optical layer. The method additionally includes totally internally reflecting light (at a surface of the concentrator) that has interacted with the second diffraction grating towards the PV cell. A method may additionally include (a) diffracting at least a portion of light received at the first diffraction grating and, alternatively or in addition, (b) totally internally reflecting at least a portion of light that has diffracted at the first diffraction grating towards the PV cell. A process of diffracting of light may include diffracting at least a portion of light received at the first diffraction grating towards the PV cell. Light transmitted through a diffraction grating and light diffracted at such diffraction grating may have different spectra.

A process of receiving of light may include receiving light with a reflection diffraction grating, while the process of transmitting of light may include transmitting light to a transmission diffraction grating.

### BRIEF DESCRIPTION OF THE DRAWINGS

The invention will be more fully understood by referring to the following Detailed Description in conjunction with the Drawings, of which:

FIG. 1 is a schematic of a holographic planar concentrator.

FIG. 2 is a top view schematic of a planar solar energy concentrator including multiple groups of PV cells.

FIG. 3 is a diagram illustrating the use of an encapsulating layer.

FIG. 4 is a diagram illustrating interaction of incident light having first spectrum with an embodiment of the invention employing a monofacial PV cell.

FIG. 5 is a diagram illustrating interaction of incident light having second spectrum with the embodiment of FIG. 4.

FIG. 6 is a diagram illustrating the operation of another embodiment of the invention.

FIG. 7 is a diagram illustrating the operation of a related embodiment employing a bifacial PV cell.

FIG. 8 is a plot depicting dependencies of diffraction efficiencies of diffraction gratings spatially multiplexed according to an embodiment of the invention, as well as diffraction angles corresponding to operational spectral bandwidths of these gratings.

### DETAILED DESCRIPTION

As broadly used and described herein, the reference to a layer as being “carried” on or by a surface of an element refers to both a layer that is disposed directly on the surface of that element or disposed on another coating, layer or layers that are, in turn disposed directly on the surface of the element.

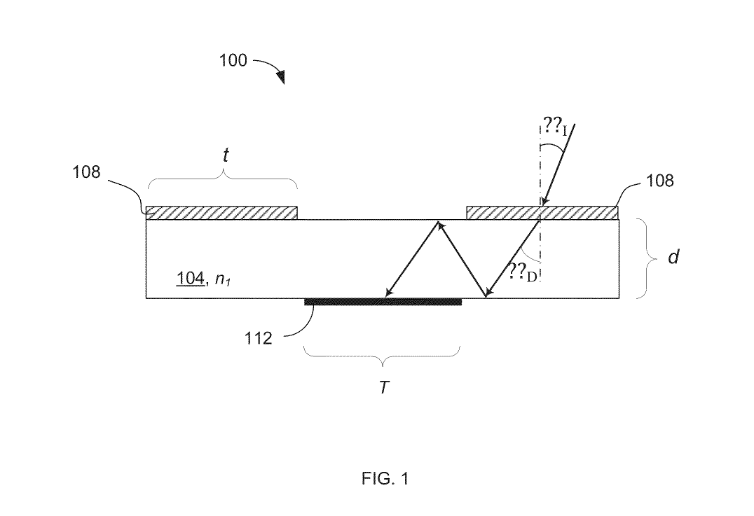

While there exists a variety of sun-light concentrators, one example of typical devices currently used for concentration of solar radiation for the purposes of PV-conversion is shown schematically in FIG. 1. An HPC 100 of FIG. 1, shown in a cross-sectional view, typically includes a highly-transparent planar substrate 104 of thickness d (such as, for example, substrate made of glass or appropriate polymeric material having the refractive index nᵢ) at least one diffractive structure 108, having width t, at a surface of the substrate 104. Such diffractive structure may include, for example, a holographic optical film (such as gelatin-on-PET film stack) in which a plurality of multiplexed diffraction gratings have been recorded with the use of laser light. The diffractive structure 108 can be optionally capped with a protective cover layer (not shown). The substrate 104 is typically cooperated with a solar-energy-collecting device 112 such as a PV cell. The diffractive structures 108 diffract wavelengths usable by the PV cell 112, while allowing the light at unusable wavelength to pass through, substantially unabsorbed. The usable energy is guided via the total internal reflection at the glass/air or glass/cover interface to strings of solar cells, resulting in up to a 3× concentration of solar energy per unit area of PV material as compared to a PV module that is devoid of such holographically-defined diffractive element.

Further in reference to FIG. 1, the PV cell 112 of width T is juxtaposed with the second surface of the substrate 104 in opposition to the diffractive structures 108 and in such orientation that ambient (sun-) light I, incident onto the structure 108 at an angle θ_{I}, is diffracted at an angle ν_{D} onto the cell 112 either directly or upon multiple reflections within the substrate 104.

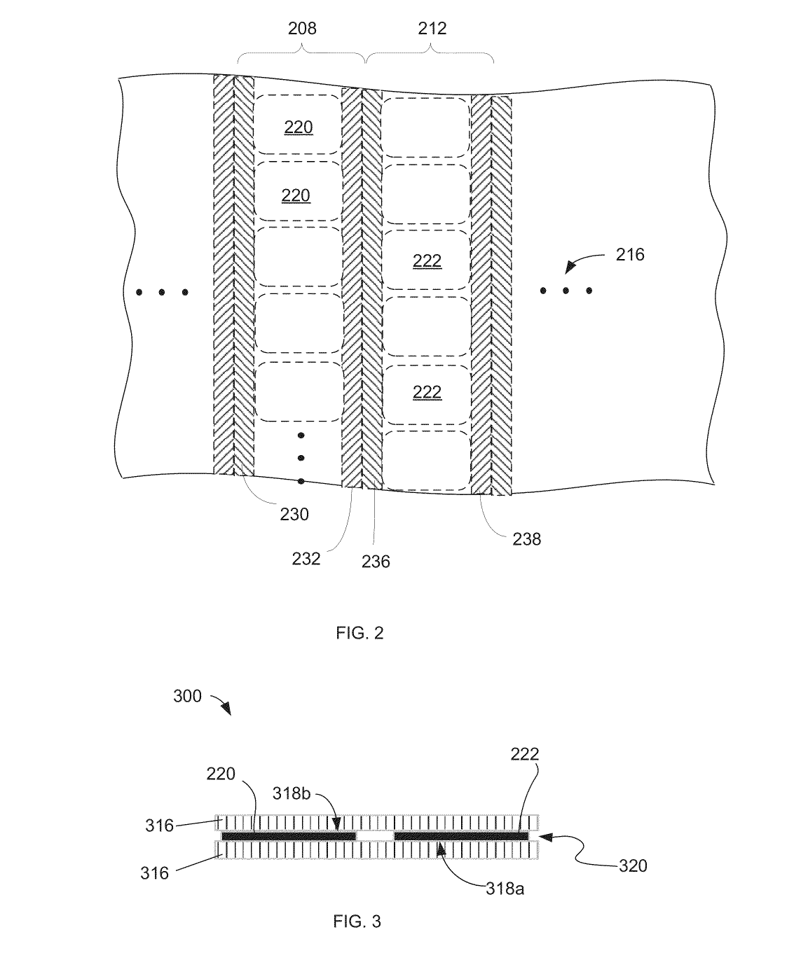

In practice, however, a PV module typically includes multiple PV cells and multiple diffractive elements in optical communications with such cells. To this end, a top view of a PV module containing an array of PV cells (whether monofacial or bifacial) is schematically shown in FIG. 2. The embodiment of FIG. 2 is a multi-portion (or multi-period) embodiment and, as shown, includes two portions 208, 212. Additional portions or periods are not shown but indicated with three-point designators 216. Each of the portions or periods 208, 212 includes a corresponding PV-cell (220 or 222) that is surrounded by (and optionally co-planar with) respectively-corresponding diffractive element layers (230, 232) or (236, 238) containing diffraction gratings (that are, optionally, holographically defined). The layers 230, 232, 236, 238 may operate in transmission, reflection, or both transmission and reflection depending on the embodiment. Various implementations describing spatial coordination of the PV cells and corresponding diffraction gratings are presented in other commonly assigned patent applications.

It is appreciated that in addition to the PV module layer and the diffractive element layer, an embodiment of the HPC of the invention may include an encapsulating layer. Because PV-cells are thin and delicate, and thereby subject to breakage or other damage, for example by scratching, chemical etching, or the like, PV-cells are optionally encapsulated with an optically and IR clear adhesive such as ethyl vinyl acetate (“EVA”) or silicone. In certain embodiments, such as that shown in FIG. 3, for instance, an encapsulant 316 is provided in the form of two sheets of EVA that are laminated to sides 318a, 318b of the PV-module layer 320 (for example, before the resulting assembly is laminated to glass, not shown, although the exact sequence of steps in the lamination process can vary). In the case of a monofacial cell, instead of one glass layer, a backsheet or protective sheet made of some polymeric material (e.g., polyethylene terepthalate (“PET”)) is optionally provided to which the PV chips are first adhered before being laminated to front side glass with an encapsulant layer. In some conventional embodiments, a backsheet is provided with encapsulant pre-deposited. In some conventional embodiments, glass is used as a backsheet, even for monofacial cells. In a related embodiment, a single encapsulant layer may be used in juxtaposition with one side of the PV-module.

The performance of diffractive optical elements and, in particular, diffraction efficiency and diffraction angle of a diffraction grating are wavelength-dependent. The spectral dependence of operational performance of a diffraction grating, for example, becomes more pronounced as the angle of deviation of light diffracted by the grating from the direction of propagation of light incident onto the grating is increased. When light incident on a diffraction grating has a very broad spectrum (which is the case for sunlight incident onto a diffractive element of a solar energy concentrator), portions of incident light at wavelengths outside of the operational bandwidth of the diffraction grating are not diffracted by the grating and are substantially transmitted by it (assuming insignificant absorbance of the material of the grating and not taking into account the residual specular reflection and scattering of light).

Embodiments of the present invention stem from the realization that an optical train of spatially multiplexed diffraction gratings can be formed to collects light that, due to its spectral content, passes through a diffraction grating of the solar energy concentrator facing the sunlight, and to redirect such light towards the PV cell of the concentrator thereby increasing the efficiency of solar energy collection without the use of additional PV cells. Such optical train of diffraction gratings is generally adapted to include a layered stack of at least two substantially planar two-dimensional gratings one of which is carried by another. In this case, the upper grating (defined, for simplicity of illustration, as the one that is facing the incident sunlight) diffracts a first portion of the incident light within the operational bandwidth of the upper grating to form a first beam of diffracted light that is further directed towards a sunlight-collecting surface of a PV cell of the system. The second portion of incident light (spectral components of which are substantially outside of the operational bandwidth of the upper grating) is transmitted by it towards the complementary lower, underlying grating and are reflected by that lower grating to form a second beam of diffracted light that is further directed towards a sunlight collecting surface of a PV cell of the system. At least one of the upper and lower diffraction gratings can be a grating holographically recorded in a material layer of the PV solar energy concentrator system of the invention. In a related embodiment, the optical train of the diffractive elements is defined by at least two diffraction gratings that are holographically recorded in the same volume of material such as to overlap in that volume. The layered structure of the system of the invention is configured to ensure that the directing of a diffracted beam of light produced by a grating of the embodiment towards a sunlight collecting surface of the PV cell is generally accomplished with the use of a total internal reflection at one of the surfaces of the solar energy concentrator system of the invention. Optical properties of a reflecting surface of the system are optionally enhanced with a reflecting thin-film layer deposited thereon.

It is appreciated that, while embodiments of the invention discussed in this application, may be discussed in reference to a concentrator system employing a monofacial PV cell, the use of bifacial PV cells is also within the scope of the invention. Similarly, a specific nature and/'or geometry of the employed diffractive elements does not change the scope of the invention. Accordingly, the examples of the embodiments are presented in reference to generalized “diffraction gratings” (such as, for example, linear or curvilinear diffraction gratings holographically recorded in a gelatin-based layer of the holographic optical film, HOF). Similarly, the spatial extent of either upper or lower diffraction grating employed in an embodiment of the invention does not change the principle of operation of the invention. While in the discussed examples it may be assumed that footprints of the upper and lower diffraction gratings of the stack (defined as extents of normal projections of these gratings on a plane of choice, for example, a plane defined by a PV cell) are substantially the same, the size of one of the gratings may generally differ from the size of another.

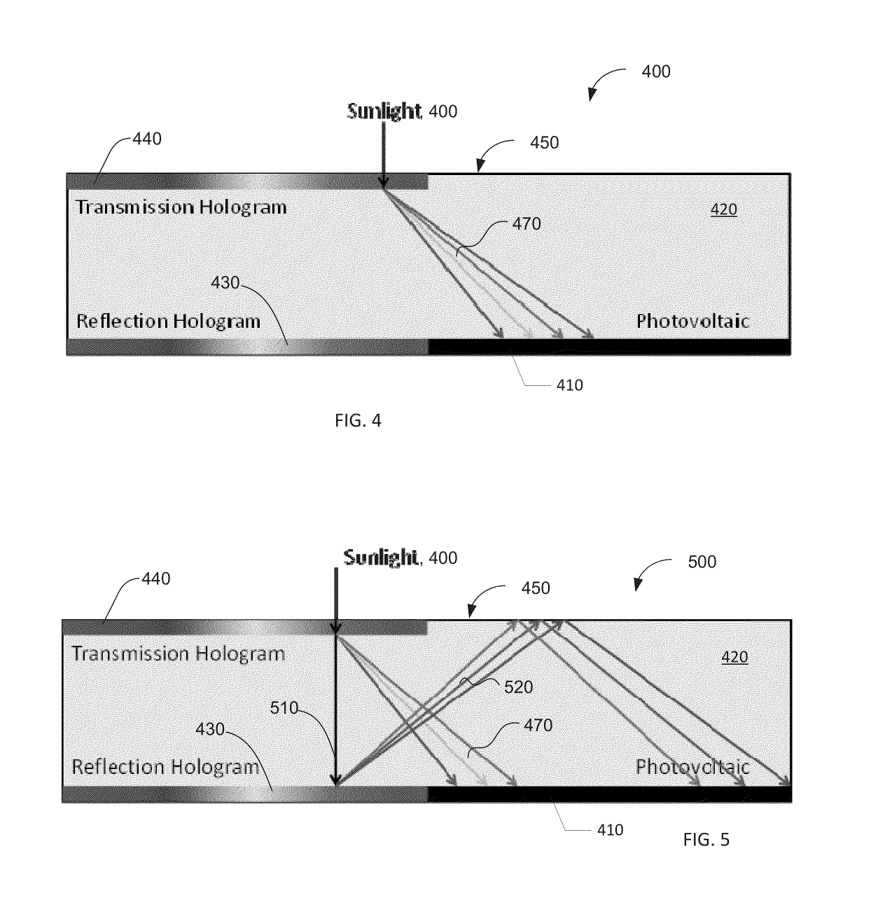

FIG. 4 illustrates an portion 400 of an embodiment of the solar-energy concentrator of the invention that includes a monofacial PV cell 410 is association with a material layer 420 (such as, for example, a layer of encapsulating material or a structural layer of glass of plastic), and a stack of two diffraction gratings 430, 440 (shown as holographic gratings operating in transmission and reflection, respectively). The lower diffraction grating 430 is affixed to or structurally associated with the same surface of the material layer 420 to which the PV cell 410 corresponds, while the upper grating 440 is at an opposite surface 450 of the layer 420, which faces the incident medium and receives incident light 460. While light 460 is shown to impinge upon the surface 450 at a substantially zero angle (defined with respect to a normal to the surface 450), generally the angle of incidence can differ from the zero angle.

As seen in FIG. 4, the portion 400 is adapted to ensure that a portion of light 470, defining a first beam of light diffracted by the grating 440 at an angle A, is directed towards the PV cell 410. When the spectral content of the incident light 460 is substantially completely falls within the operational bandwidth of the upper diffraction grating 440, a portion of light transmitted through the grating 440 towards the underlying lower grating 430 is insignificant, if any. If, however, the light 460 includes, in addition, spectral components outside of the operational bandwidth of the grating 440, the incident light 460 forms, upon interaction with the grating 440, not only the first diffraction beam 470 but also a transmitted beam 510 (as shown in an embodiment 500 of FIG. 5). The transmitted beam 510 propagates through the layer 410 towards the lower grating 420 and is at least partially diffracted at it to form a second diffracted beam 520. The embodiment 500 is configured such that the second diffracted beam 520 is substantially totally internally reflected at the upper surface 450 of the layer 420. (To ensure such TIR, the design of the grating 430 includes a consideration of the distribution of refractive index of the material layer 420 as well as the spectral content of the transmitted beam 510). Having experienced the TIR at the surface 450, the second diffracted beam 470 is redirected towards the PV cell 410. Accordingly, in comparison with the situation when the embodiment 500 is devoid of the lower grating 430 (not shown), the structure of FIG. 5 facilitates collection of light, at the PV cell, that has been transmitted through the upper diffraction grating 440 without diffraction.

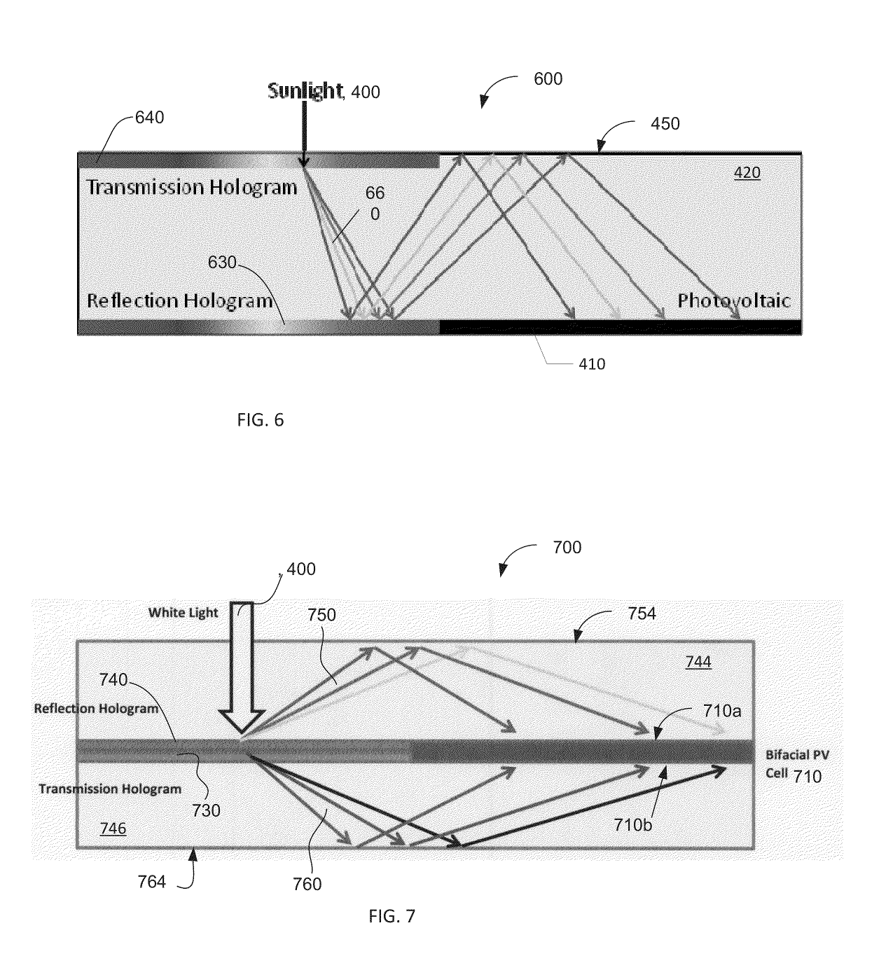

FIG. 6 illustrates another embodiment, where the geometry and/or optical properties of the diffraction grating stack 630, 640 are chosen such that the first diffracted beam 650 impinges onto the lower diffraction grating 630 at an angle B and is further diffracted by the grating 630 at an angle B′ to form a second diffraction beam 660 (which, in turn, is totally internally reflected, as shown, on the surface 450). If the dimensions of the gratings 430 and 630 are substantially the same, and that the same hold true for the gratings 440 and 640 (of the embodiments 500, 600 of FIGS. 5 and 6), the angle B of diffraction of light at the grating 640 is smaller than the angle A of diffraction of light at the grating 440. The embodiment 600 is optionally configured such that he angle B′ of diffraction of light at the grating 640 is also smaller than the corresponding angle A′ corresponding to the grating 440. It is understood that both gratings 630, 640 are optimized for the same spectral bandwidth. Because the angle of diffraction at a diffraction gratings is inverse with respect to its operational spectral bandwidth (other operational characteristics being substantially the same), the embodiment 600 of FIG. 6 delivers light to the PV cell 410 within a broader spectral bandwidth as compared to that of the embodiment 500 of FIG. 5.

A cross-sectional view of an embodiment 700 of the invention in FIG. 7 is shown, not to scale, to include a bifacial PV cell 710 and a stack of immediately adjacent diffraction gratings 730, 740. In contradistinction with the gratings of the embodiments 400, 500, 600 of FIGS. 4, 5, and 5, the upper grating 740 is configured to operate in reflection and the lower grating 730 carrying the grating 740 is configured to operate in transmission. Both the bifacial cell 710 and the spatially multiplexed gratings 730, 740 are shown to be encapsulated and/or sandwiched and/or laminated between material layers 744 and 746. A portion of incident light 400 that is diffracted by the upper grating 740 forms a first diffraction beam 750 that is TIR'ed at an upper surface 754 of the layer 744 and is further directed towards an upper light-collecting surface 710a of the PV cell 710. A portion of incident light 400 having spectral content outside of the operational bandwidth of the grating 740 is transmitted through the gratings 740 and is diffracted, also in transmission, at the grating 730 to form a second diffraction beam 760 that is totally internally reflected at a bottom surface 764 of the layer 746. Having been TIR'ed, the beam 760 and is further directed to the second light-collecting surface 710b of the PV cell 710.

In another embodiment (not shown) related to that of FIG. 7, the two or more stacked or spatially multiplexed diffraction gratings can be holographically recorded such as to overlap in the same volume (or “volume multiplexed”). To this end, two or more substantially spectrally complementary portions of light incident onto such “diffraction volume” will interact with the two or more gratings recorded therein. Each of the gratings is configured to produce a respectively corresponding diffraction beam that is further redirected (optionally, with the use of the TIR effect at one of the surfaces of the embodiment) towards the PV cell of the embodiment.

Generally, an embodiment of the solar energy concentrator configured according to the idea of the invention may include more than two spatially multiplexed diffractive elements at least one of which carries another. For example, in further reference to FIG. 7, a second holographic grating operating in reflection in a near infrared (near-IR) bandwidth such as, for example, the spectral region between about 900 nm and about 1100 nm, can be added to the diffraction grating stack of FIG. 7 (either above or below the grating 740) such as to diffract the light within its near-IR bandwidth towards one of the surfaces of the bifacial PV cell 710.

In a related embodiment (not shown), an auxiliary diffraction grating can be added, along a surface of any of the embodiments discussed above, to interact with light residually reflected at a surface of a grating from the stack of gratings (which otherwise is not delivered to the PV cell). A person skilled in the art will appreciate that additional encapsulating layers and/or optically transparent structural layers can be added to allow for reversal of the order in which diffraction gratings are disposed in the stack without affecting the principle of operation of the embodiment. For example, in reference to FIGS. 5 and 6, an additional encapsulating layer can be added on top of the layer 420, in which case the upper grating 440 can be configured to operate in reflection and the lower grating 430 can be configured to operate in transmission.

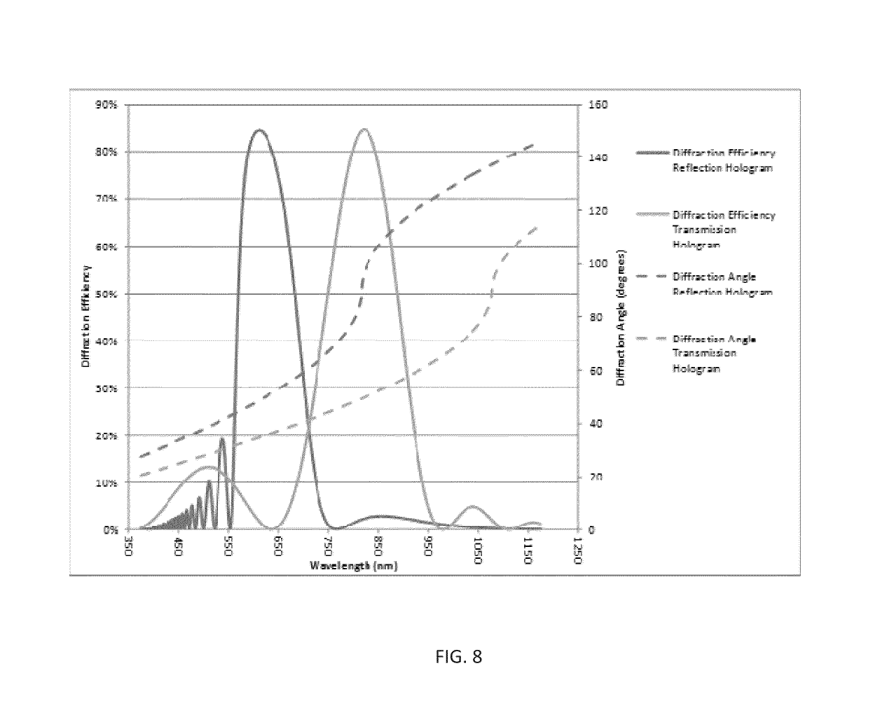

FIG. 8 is a plot depicting dependencies of diffraction efficiencies of diffraction gratings spatially multiplexed according to an embodiment of the invention, as well as diffraction angles corresponding to operational spectral bandwidths of these gratings. Diffraction angles are defined with respect to lines that are perpendicular (i.e., the normals) to the surfaces of the corresponding gratings.

It is appreciated that at least some of the definitions of a pattern of a diffractive element layer of an embodiment, a disposition of the diffractive element layer over and in a required spatial coordination with the PV-module layer, and other system configuring and/or method step definition elements of the invention may be effectuated or supplemented with a processor controlled by instructions stored in a memory. The memory may be random access memory (RAM), read-only memory (ROM), flash memory or any other memory, or combination thereof, suitable for storing control software or other instructions and data. Instructions or programs defining the functions of the present invention may be delivered to a processor in many forms, including, but not limited to, information permanently stored on non-writable storage media (e.g. read-only memory devices within a computer, such as ROM, or devices readable by a computer I/O attachment, such as CD-ROM or DVD disks), information alterably stored on writable storage media (e.g. floppy disks, removable flash memory and hard drives) or information conveyed to a computer through communication media, including wired or wireless computer networks. In addition, while the invention may be embodied in software, the functions necessary to implement the invention may optionally or alternatively be embodied in part or in whole using firmware and/or hardware components, such as combinatorial logic, Application Specific Integrated Circuits (ASICs), Field-Programmable Gate Arrays (FPGAs) or other hardware or some combination of hardware, software and/or firmware components. Accordingly, a computer program product containing a computer program with program code causing a processor to implement, supplement, effectuate the method and/or system of the invention are within the scope of the invention.

The invention should not be viewed as being limited to the disclosed embodiments. Envisioned claims may be directed to at least a system and/or method for fabrication of a holographic optical film preform, an article of manufacture produced with the use of such system and/or method, and a computer program product for use with a system and/or method of an embodiment of the invention.

1. A solar energy concentrator having a front positioned, in operation, to be exposed to sunlight, the concentrator comprising
a photovoltaic (PV) module layer including a PV cell that defines a plane corresponding to the front;
a first diffraction grating; and
a second diffraction grating corresponding to the front, the second diffraction grating disposed such that sunlight that has interacted with the second diffraction grating interacts with the first diffraction grating.

2. A solar energy concentrator according to claim 1, wherein the second diffraction grating is structured to transmit a portion sunlight from the front towards the first diffraction grating.

3. A solar energy concentrator according to claim 1, wherein the first and second diffraction gratings include holographic diffraction gratings.

4. A solar energy concentrator according to claim 3, wherein the first and second diffraction gratings overlap in space.

5. A solar energy concentrator according to claim 1, wherein the first and second diffraction gratings have substantially co-extensive normal projections on the plane defined by the PV cell.

6. A solar energy concentrator according to claim 1, wherein the first and second diffraction gratings are adjoining one another.

7. A solar energy concentrator according to claim 1, further comprising an optical layer separating the first and second diffraction gratings.

8. A solar energy concentrator according to claim 7, wherein the first diffraction grating is behind the second diffraction grating as viewed from the front, and the concentrator configured to ensure that light that has interacted with the first diffraction grating is totally internally reflected by a surface of the optical layer towards the PV cell.

9. A solar energy concentrator according to claim 8, wherein the PV cell includes a monofacial PV cell.

10. A solar energy concentrator according to claim 1, further comprising first and second optically-transparent substrates sandwiching said photovoltaic module layer, said first diffraction grating, and said second diffraction grating therebetween to define an optical stack, said second substrate corresponding to the front, said optical stack configured to ensure that light that has interacted with the second diffraction grating is totally internally reflected by a surface of the optical stack towards the PV cell, and that light that has interacted with the first diffraction grating is totally internally reflected by a surface of the optical stack towards the PV cell.

11. A solar energy concentrator according to claim 10, wherein the PV cell includes a bifacial PV cell and the optical stack is configured to have the light, which has interacted with the first diffraction grating, to be received by a face of the PV that is opposite to the front.

12. A solar energy concentrator according to claim 10, wherein a surface of the optical stack reflecting light that has interacted with the second diffraction grating includes a surface of the second substrate.

13. A method for collecting sunlight with a planar layered solar energy concentrator having a front and a photovoltaic (PV) cell, the method comprising:
receiving sunlight at a first diffraction grating defining a first optical layer of said concentrator, the first diffraction grating corresponding to the front;
transmitting at least a portion of said light received with the first diffraction grating to a second diffraction grating defining a second optical layer of said concentrator, the second optical layer configured to carry the first optical layer; and
totally internally reflecting light that has interacted with the second diffraction grating, at a surface of said concentrator, towards the PV cell.

14. A method according to claim 13, further comprising diffracting at least a portion of said light received at the first diffraction grating.

15. A method according to claim 14, further comprising totally internally reflecting at least a portion of light that has diffracted at the first diffraction grating, at a surface of said concentrator, towards the PV cell.

16. A method according to claim 14, wherein said diffracting includes diffracting at least a portion of said light received at the first diffraction grating towards the PV cell.

17. A method according to claim 14, wherein said transmitting includes transmitting first light and said diffracting includes diffracting second light, the first and second light having different spectra.

18. A method according to claim 13, wherein said receiving includes receiving light with a reflection diffraction grating and said transmitting includes transmitting light to a transmission diffraction grating.

19. A method according to claim 13, wherein said totally reflecting includes totally reflecting light towards a back surface of the bifacial cell.

20. A method according to claim 19, further comprising diffracting said received at the first diffraction grating to form first diffracted light and totally reflecting said first diffracted light towards a front surface of the PV cell.
